(19) United States
(12) Patent Application Publication
(10) Pub. No.: US 2025/0332831 A1
(43) Pub. Date: Oct. 30, 2025

(54) DRY FILM MEMBRANE TENTING

(71) Applicant: FUJIFILM DIMATIX, INC., Lebanon, NH (US)

(72) Inventors: Eric Sanjuan, Lebanon, NH (US); Kevin von Essen, Lebanon, NH (US); Sean Cahill, Lebanon, NH (US)

(21) Appl. No.: 18/649,809

(22) Filed: Apr. 29, 2024

(51) Int. Cl. B41J 2/14; B41J 2/16; G03F 7/00; G03F 7/20

(52) U.S. Cl. CPC B41J 2/14064; B41J 2/14024; B41J 2/14072; B41J 2/1601; B41J 2/1623; B41J 2/1631; B41J 2/164; G03F 7/0035; G03F 7/2002; B41J 2002/14491

(57) ABSTRACT

Apparatuses (e.g., inkjet printheads) having a dryfilm tenting structure and methods for fabricating the same are disclosed. In some embodiments, an inkjet printhead comprises a first actuator substrate having one or more cavities for fluid routing and include an actuator cavity; an actuator stack coupled to the first structure and positioned at least partially over the actuator cavity, the actuator stack comprising a membrane, an actuator coupled to a first side of the membrane, and a tented structure coupled to the actuator substrate to create an enclosed cavity large enough to enable the membrane in the cavity to bow without contacting the tented structure.

### FIELD OF THE DISCLOSURE

Embodiments of the present disclosure are related to inkjet printhead construction; more particularly, embodiments disclosed herein related to inkjet printhead with a tented structure.

### BACKGROUND

Inkjet printheads can be fabricated using known micromachining techniques to produce highly precise and repeatable devices in large arrays, in some instances including thousands of actuating elements. Each jetting element in these arrays is highly energetic, creating pressure pulses that allow the controlled ejection of fluid droplets. The aforementioned jets are of modest efficiency, with excess energy moving throughout the head, sometimes producing undesired large-scale modal displacements. These physical displacements of the overall head can, in turn, produce visible variation in print patterns. An example of such a variation, or print defect, is banding. Banding shows up as variation in color which the human eye is well-equipped to notice. Thus, it is desirable to reduce or otherwise suppress such print defects.

Micromachined printheads are often fabricated from materials such as silicon, which has a high elastic modulus, and so can be quite stiff. On the other hand, given the high density of fluid-containing actuators, and of the plumbing required to supply fluid to these actuators, the structure of a typical printhead is not solid, but hollowed out to accommodate the actuators and to allow the flow of liquid, thus effectively un-stiffening the overall structure versus a structure that is solid.

Polymer layer stacking has been employed for some time to realize microfluidic structures. Such work laminating paper and tape was described by Whitesides, et al (Three-dimensional microfluidic devices fabricated in layered paper and tape (pnas.org)) to create bioassays. Subsequent work by Meier, et al describes the lamination of PerMX DryFilm photoresist for the manufacturing of 3-D multi-level microfluidic networks (Complex three-dimensional high aspect ratio microfluidic network manufactured in combined PerMX dry-resist and SU-8 technology|Biomicrofluidics|AIP Publishing). Wangler, et al describes the use of multiple layers of dryfilm to both create gaps and bridge over the gaps to realize sealed microfluidic structures with minimal sagging of the second laminated layer (High-resolution permanent photoresist laminate TMMF for sealed microfluidic structures in biological applications-IOPscience). Patterned photopolymer films have been employed for use in inkjet printheads e.g., as nozzle plates (US20120274707A1), or as part of sealed actuators immersed in fluid containment chambers (U.S. Pat. No. 10,946,653 B2). Such films are available from Tokyo Ohka Kogyo, Nagase-EMS, Dupont, and others.

### SUMMARY

Apparatuses (e.g., inkjet printheads) having a dryfilm tenting structure and methods for fabricating the same are disclosed. In some embodiments, an inkjet printhead comprises a first actuator substrate having one or more cavities for fluid routing and include an actuator cavity; an actuator stack coupled to the first structure and positioned at least partially over the actuator cavity, the actuator stack comprising a membrane, an actuator coupled to a first side of the membrane, and a tented structure coupled to the actuator substrate to create an enclosed cavity large enough to enable the membrane in the cavity to bow without contacting the tented structure.

In some embodiments, a method of manufacturing an inkjet printhead for expelling a droplet of a fluid through a nozzle orifice, comprises: laminating a first photosensitive dryfilm onto an actuator substrate having one or more cavities for fluid routing and include an actuator cavity, wherein a first side of a membrane is coupled to the actuator substrate and an actuator is coupled to a second side of the membrane that is opposite the first side; and creating a tented structure coupled to the actuator substrate using the first photosensitive dryfilm, the tented structure enclosing a cavity around the actuator and large enough to enable the membrane in the cavity to bow without contacting the tented structure.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 illustrates some embodiments of an inkjet printhead.

FIG. 2 illustrates a simulation of the allowed bending in the structure of FIG. 1.

FIG. 3 illustrates an example of print, or grayscale, banding behavior.

FIG. 4 illustrates some embodiments of an inkjet printhead structure with a tented structure.

FIG. 5 illustrates a section view through some embodiments of a fabricated inkjet printhead device.

FIG. 6 shows Laser Doppler Velocimetry images of the inkjet printhead constructions of FIGS. 1 and 4.

FIG. 7 shows the velocimetry response over frequency of the inkjet printhead constructions of FIGS. 1 and 4.

FIG. 8 illustrates some embodiments of an inkjet printhead that is a modified version of FIG. 4 that includes the use of spacers or travel stops.

FIG. 9 illustrates some embodiments of a modification of the inkjet printhead in FIG. 4 that includes routing of electrodes and/or traces on the top of dryfilm.

FIG. 10 illustrates some embodiments of a modification of the inkjet printhead in FIG. 4 in which dryfilm and an IP form the tented structure.

FIG. 11 is a flow diagram of a process for manufacturing an inkjet printhead for expelling a droplet of a fluid through a nozzle orifice.

FIG. 12 is a flow diagram of a process for creating some embodiments of a tented structure.

### DETAILED DESCRIPTION

In the following description, numerous details are set forth to provide a more thorough explanation of embodiments of the present disclosure. It will be apparent, however, to one skilled in the art, that the teachings disclosed herein may be practiced without these specific details. In other instances, well-known structures and devices are shown in block diagram form, rather than in detail, in order to avoid obscuring the present disclosure.

Printheads are often constructed of several layers, for which it is highly desirable to make as rigid an attachment as possible in order to maintain as much stiffness as possible in the overall structure. Thus, it is desirable to make rigid attachments where possible, and where not possible, to maximize the bonded area between layers to reduce undesired mechanical displacements. Thus, it is also desirable to establish this attachment while reducing, minimizing or eliminating the risk of adhesive impingement onto jetting actuators. Additionally, it is desirable to dissipate excess energy where possible in ways that do not produce undesired mechanical displacements and print defects.

Embodiments described herein include inkjet printheads and method for fabricating the same that satisfy one or more of the desirable features described above. In some embodiments, such printheads include the use of one or more dryfilms. Such dryfilms can be used to form tented structures over pumping chambers, or portions thereof (e.g., actuators, membranes, ink cavities and channels, and nozzles, etc.). In some embodiments, the inkjet printheads use two dryfilms to form the tented structure. In some embodiments, one or more dryfilms are coupled, or attached, to other parts of the inkjet printhead to make the construction of the inkjet printhead more durable in light of mechanical and energy stresses it undergoes during operation.

In some embodiments, an inkjet printhead comprises multiple functional layers. Such a printhead can have layers for the jet actuators, ink routing and jet chambers, nozzles, and for distribution of fluid. In some embodiments, these layers are assembled with adhesive and constructed to avoid other functional layers. For example, in some embodiments, the jet actuators require a supply of fluid, but also need to be able to displace. Although the distances involved can be quite small (e.g., less than 0.5 um), if jet actuators are impeded, either by other structures or by adhesives, their performance is likely to be adversely affected. These adverse effects can range from small amounts of energy or displacement reduction to complete loss of function.

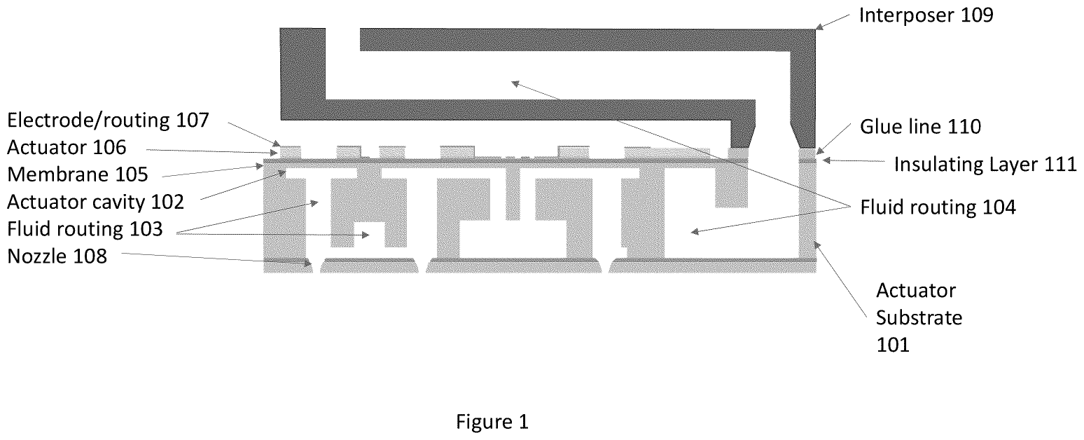

FIG. 1 illustrates some embodiments of an inkjet printhead. Referring to FIG. 1, the inkjet printhead includes an actuator substrate 101 having actuator cavities, such as, for instance, actuator cavity 102. In some embodiments, actuator substrate 101 is part of a jetting die. Actuator substrate 101 also includes a number of chambers, channels and passages for fluid routing, such as, for example, fluid routing 103 and 104 as well as nozzles, such as, for example, nozzle 108, at the ends of actuator cavities for outputting or otherwise discharging fluid. In some embodiments, the fluid is ink, but need be limited to ink. A membrane layer 105 is coupled to, or attached, to the top of actuator substrate 101. Jet actuators, such as, for example, actuator 106, are coupled to, or attached to membrane layer 105. In some embodiments, jet actuators are coupled to membrane layer 105 via an electrically insulating layer 111. Electrodes (and other electrical traces) 107 are routed to and on actuators 106. In some embodiments, the actuators (e.g., actuator 106), membrane layer 105, and actuator cavities (e.g., actuator cavity 102), and nozzles 108 form pumping chambers.

An interposer (IP) 109 is coupled, or attached, to actuator substrate 101 to route fluid to actuator substrate 101 and its chamber, channels and passages. In some embodiments, interposer 109 is attached to actuator substrate 101 using glue (e.g., glue line 110) or some other adhesive.

The construction of the inkjet printhead in FIG. 1 allows fluid routing yet has some detrimental impact on performance. In some embodiments, the attachment (e.g., glue attachment) between interposer (IP) 109 and actuator substrate 101 (e.g., jetting die, etc.) is far from any actuator (e.g., actuator 106) and has a small risk of interaction. Such a structure, however, is essentially a cantilever that can bend and bow quite freely as it has minimal constraints.

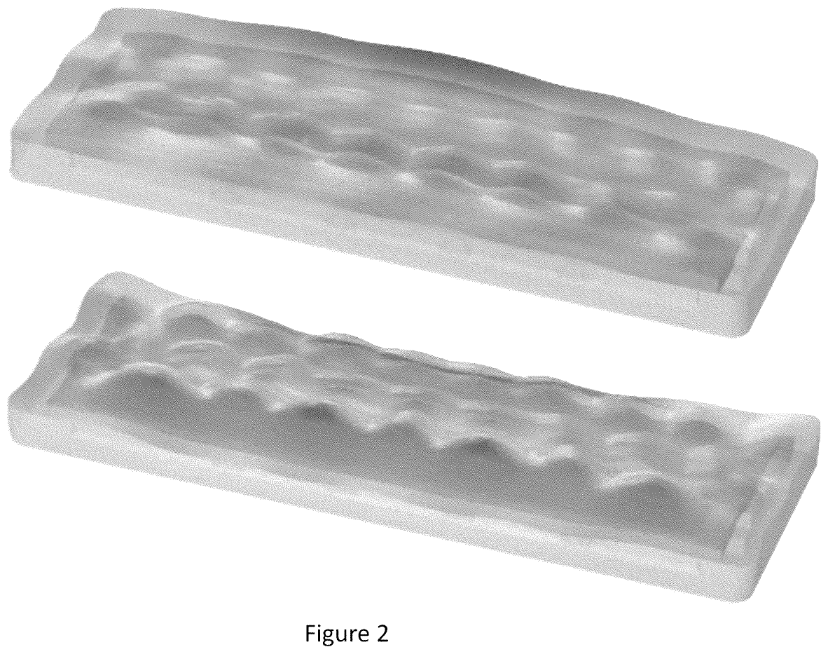

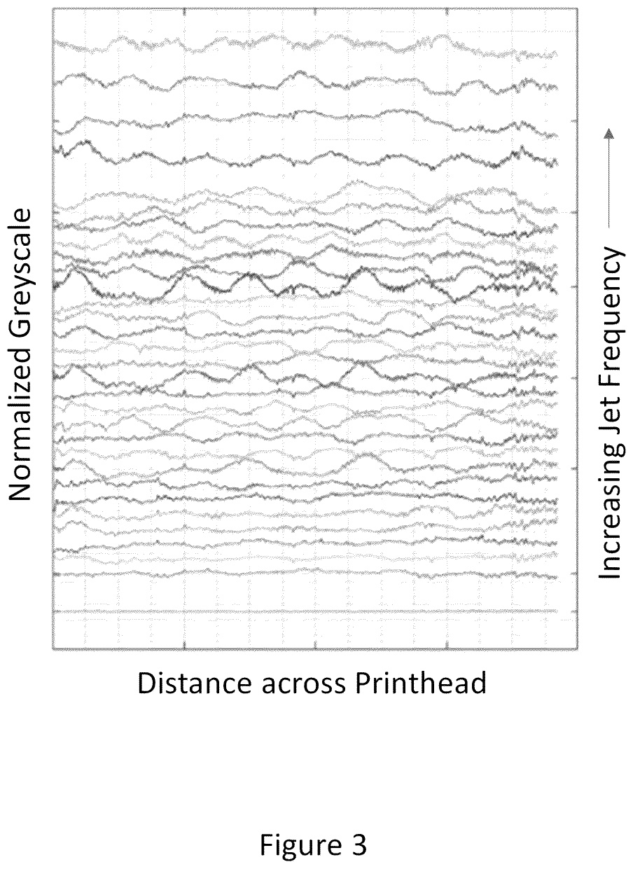

FIG. 2 illustrates a simulation of the allowed bending in the structure of FIG. 1. Referring to FIG. 2, the overall bending of the structure from end to end and many (8-10) higher-order nodes/anti-nodes that occur near the operational frequency of the printhead are shown. These vibrations can couple into the mechanical structure and the fluids. This coupling can lead to print artifacts, such as, for example, the print banding described earlier. FIG. 3 illustrates this print, or grayscale, banding behavior. Note that the spatial frequency of greyscale bands increases with operational frequency. Also, at particular frequencies, the relative amplitude varies. Both of these behaviors are undesirable. One purpose of the techniques described herein is to reduce, and potentially minimize, the undesired vibrational mode behavior illustrated in FIG. 2, and the consequent greyscale banding depicted in FIG. 3.

As discussed herein, in some embodiments, multiple layers of dryfilm can be used to both create gaps, and bridge(s) over the gaps, to realize cavity structures with reduced, and potentially minimal, sagging of a second laminated layer. Such cavity structures constructed over actuators can prevent the subsequent intrusion of adhesives used to establish strong and frequent points of attachment for multiple constructed layers. Establishing strong and frequent points of attachment for multiple constructed layers allows for large areas of relatively rigid attachment, stiffening the overall structure, and substantially reducing vibration mode amplitudes over a frequency range of interest.

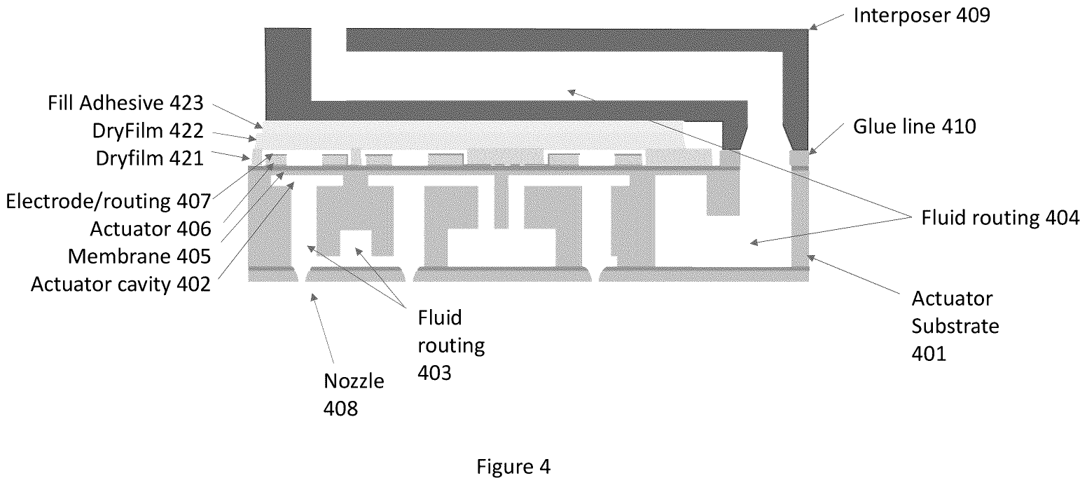

FIG. 4 illustrates some embodiments of an inkjet printhead structure with the construction described above. Referring to FIG. 4, the inkjet printhead includes an actuator substrate 401 having actuator cavities, such as, for instance, actuator cavity 402. In some embodiments, actuator substrate 401 is part of a jetting die. Actuator substrate 401 also includes a number of chambers, channels and passages for fluid routing, such as, for example, fluid routing 403 and 404 as well as nozzles, such as, for example, nozzle 408, at the ends of actuator cavities for outputting or otherwise discharging fluid. In some embodiments, the fluid is ink, but need not be limited to ink.

A membrane layer 405 is coupled to, or attached, to the top of actuator substrate 401. Jet actuators, such as, for example, actuator 406, are coupled to, or attached to membrane layer 405. Electrodes (and other electrical traces) 407 are routed to and on actuators 406. In some embodiments, the actuators (e.g., actuator 406), membrane layer 405, and actuator cavities (e.g., actuator cavity 402), and nozzles 408 form pumping chambers.

A dryfilm layer 421 is coupled, or attached, to membrane layer 405. In some embodiments, a bottom (first) surface of dryfilm layer 421 is coupled to portions of membrane layer 405. In some embodiments, dryfilm layer 421 is a photosensitive polymer laminated onto and over the top of the actuators (e.g., actuator 406), membrane layer 405 and electrodes (and electrical traces) 407. Certain portions of dryfilm layer 421 over the membrane and actuators having been removed or otherwise extracted during the fabrication process. Dryfilm layer 422 is coupled, or attached, to the remaining portions of dryfilm layer 421. In some embodiments, a bottom (first) surface of dryfilm layer 422 is coupled to top (remaining) portions of dryfilm layer 421, effectively forming cavities over and enclosing the actuators and the portion of the membrane layer 405 within the cavities. In some embodiments, dryfilm layer 421 and dryfilm layer 422 together create a tented structure that encloses a cavity large enough to enable the portion of membrane layer 405 in the cavity to undergo deflection (e.g., bow) without contacting the tented structure.

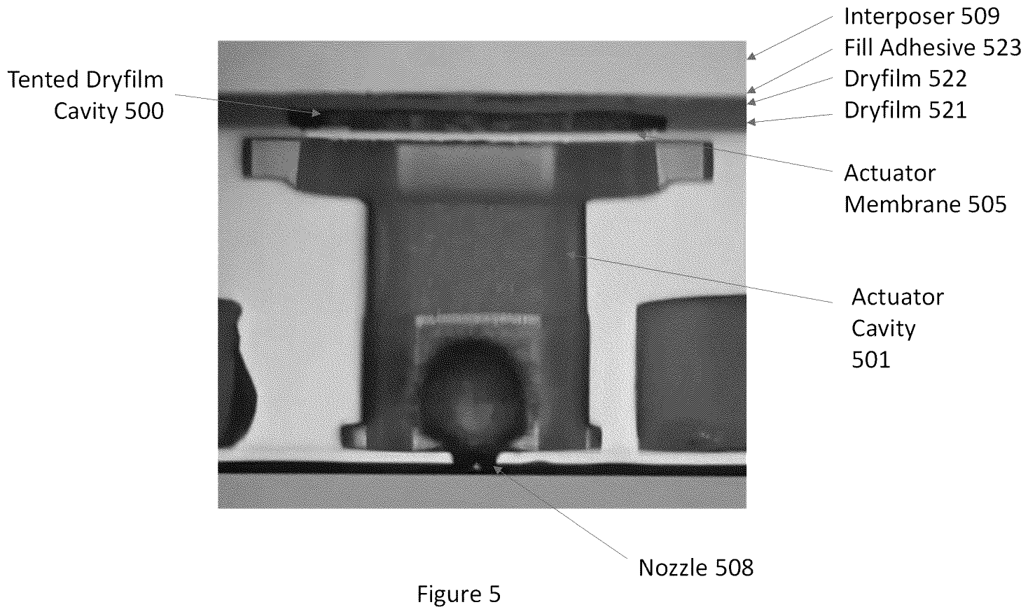

FIG. 5 illustrates a section view through some embodiments of a fabricated inkjet printhead device. Referring to FIG. 5, the section view of inkjet printhead device shows a nozzle 508, an actuator cavity 501 and an actuator membrane 505, which can form part of a pumping chamber. Over actuator membrane 505 is tented dryfilm cavity 500 formed by dryfilms 521 and 522. This tented dryfilm cavity 500 structure encloses a cavity large enough to enable the portion of actuator membrane 505 in dryfilm cavity 500 to deflect (e.g., bow) without contacting dryfilm cavity 500. Fill adhesive 523 couples, or attaches, the top of dryfilm 522 of tented dryfilm cavity 500 to interposer 509.

The resulting “tented” structure can now be connected (e.g., glued, etc.) to other parts of the inkjet printhead device. In this case, this connection involves the interposer (IP) at the original fluid feedthrough area, as well as over the entire actuator containing area. Referring back to FIG. 4, IP 409 is coupled, or attached, to actuator substrate 401 to route fluid to actuator substrate 401 and its chamber, channels and passages. In some embodiments, a fill adhesive 423 attaches, or couples, interposer 409 to the top surface of dryfilm 422 that is opposite the bottom surface of dryfilm 422 that is coupled, or attached, to dryfilm 421. In some embodiments, IP 409 is also attached to actuator substrate 401 using glue or some other adhesive. Fill adhesive 423 depicted in FIG. 4 should adhere well to both IP 409 and the second dryfilm layer 422. In some embodiments, fill adhesive 423 can be applied directly onto the dryfilm 422 or IP 409 prior to bringing IP 409 and rest of the inkjet printing device (e.g., the jetting die) together. In some embodiments, fill adhesive 423 is as a liquid. In some other embodiments, fill adhesive 423 is an adhesive preform. In some embodiments, fill adhesive 423 also can be dispensed through capillary fill after bringing IP 409 and rest of the inkjet printing device (e.g., the jetting die) together, much like the underfill used in integrated circuit packaging, such as for flip-chip assemblies. There are multiple considerations when choosing the fill adhesive material including thermo-mechanical properties (e.g., thermal expansion coefficient, thermo-viscous effects, chemical interactions, moisture or solvent absorption, swelling, reflow, adhesion, etc.) that can beneficially impact overall performance.

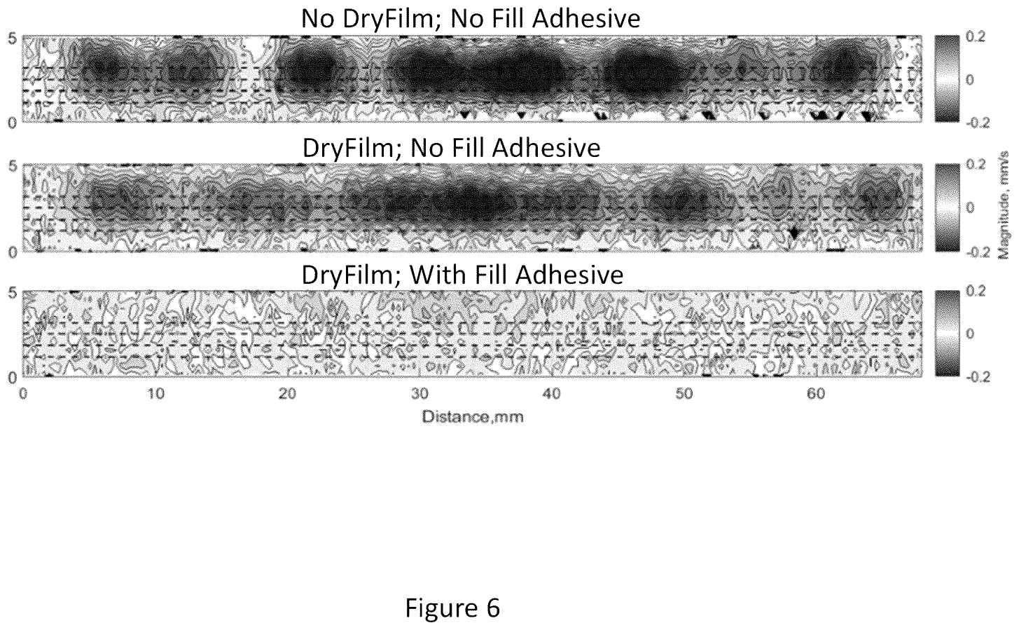

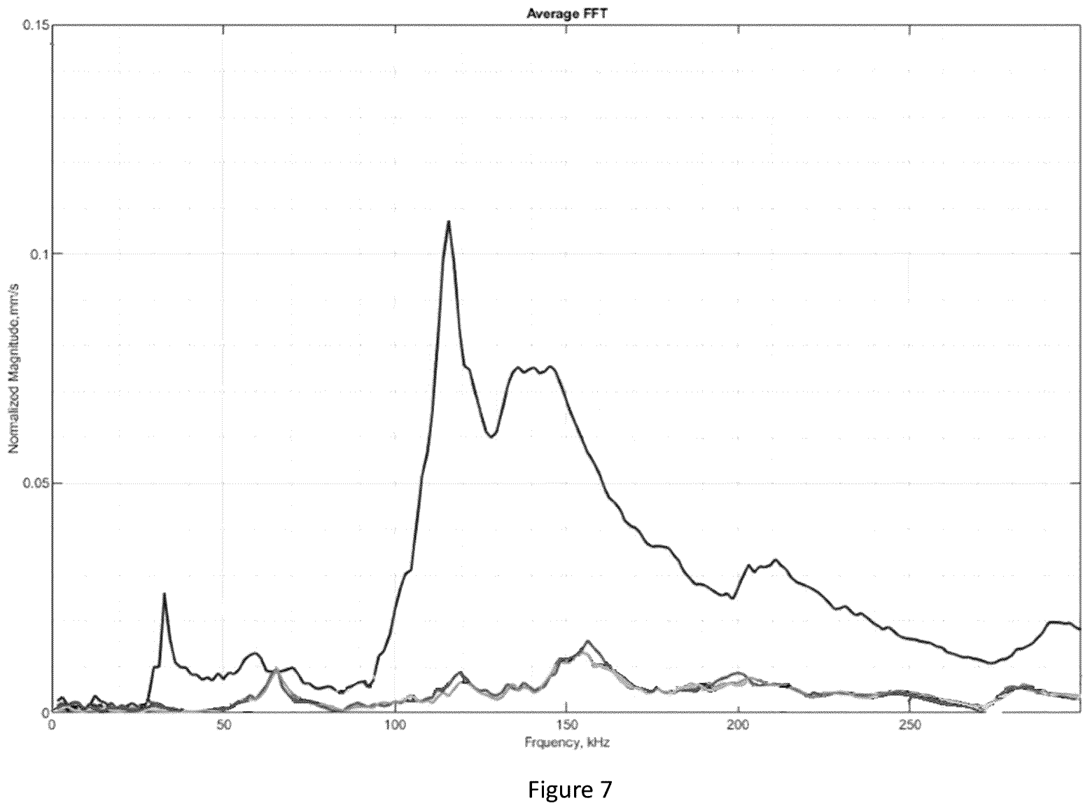

The resulting printhead performance is significantly improved. FIG. 6 shows Laser Doppler Velocimetry images of the inkjet printhead constructions of FIGS. 1 and 4, the latter both with and without the fill adhesive described above. The dark portions indicate areas of high displacement. Note that the dryfilm in combination with the fill adhesive achieves a large reduction in displacement. FIG. 7 shows the velocimetry response over frequency.

Note that the combination of dryfilm(s) plus fill adhesive achieves reduced displacement over all frequencies of interest, in the most dramatic case by more than an order of magnitude. As discussed above, actuator deflection can be less than 0.5 um, so by choosing the support layer (e.g., dryfilm 421) to be of sufficient thickness, only a small fraction of the cavity volume is compressed, and thus acoustic effects from the dryfilm cavity volume are negligible. In some embodiments, the support layer is in a range from 5-40 um in thickness, with 20 um being a typical value.

The construction of the inkjet printhead device depicted in FIG. 4 can be further modified to permit other performance and design advantages. For example, in order to obtain repeatable assembled dimensions and vibrational behavior, it is useful to control the glue bond lines (thickness) consistently. It is also desirable to prevent the glue line from becoming too thin, resulting in improper curing of multi-component adhesives. This is sometimes achieved by using adhesives containing fillers, but chemical compatibility considerations may preclude the use of such fillers. Dryfilm layers can be used as construction layers, providing control of adhesive thickness through the use of spacers or travel stops.

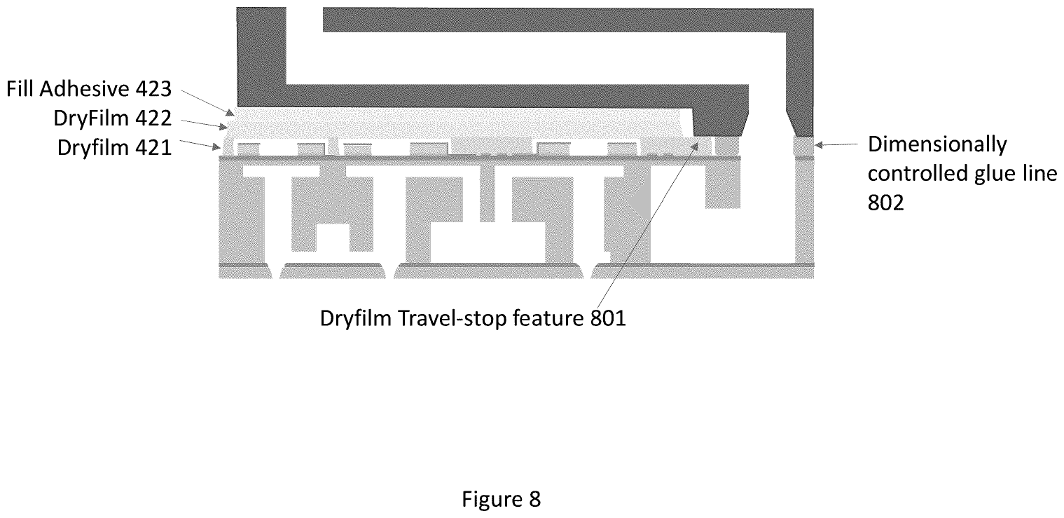

FIG. 8 illustrates some embodiments of an inkjet printhead that is a modified version of FIG. 4 that includes the use of spacers or travel stops. Referring to FIG. 8, dryfilms 421 and 422 create a tented structure on top of actuator substrate 401 and the top of dryfilm 422 is coupled to IP 409 via fill adhesive 423. In contrast to FIG. 4, IP 409 is also coupled, or attached, to dryfilm 421 with a dryfilm travel-stop (e.g., spacer) feature 801 and coupled to actuator substrate 401 via a dimensionally controlled glue line 802. Dryfilm travel-stop feature 801 operates to prevent the glue (or other adhesive) that couples IP 409 to actuator substrate 802 from spreading beyond the end of dryfilm travel-stop feature 801 during assembly of the inkjet printhead.

While constructions that include dryfilm are disclosed here, including its use in forming cavities and providing assembly assist features, they can also serve as leave-in dielectric for increased levels of integration. For example, the printheads depicted in FIGS. 1, 4, and 8 utilize areas of the die adjacent to actuators for routing of electrical lines. With the inclusion of dryfilm, routing of these electrical lines need not consume precious die area but can be routed on the dryfilm surface. This allows greater compactness of design, and/or widening of routing traces to improve current carrying capacity and defect (shorts/opens) susceptibility. Thus, both yield and performance can be improved. For example, in FIG. 8, the electrode and trace routing can be on the top surface of membrane layer, on top of any insulating layer over the membrane layer, on the top surface of dryfilm 421, and/or the top surface of dryfilm 422. Such routing can extend between these layers using, for example, via connections.

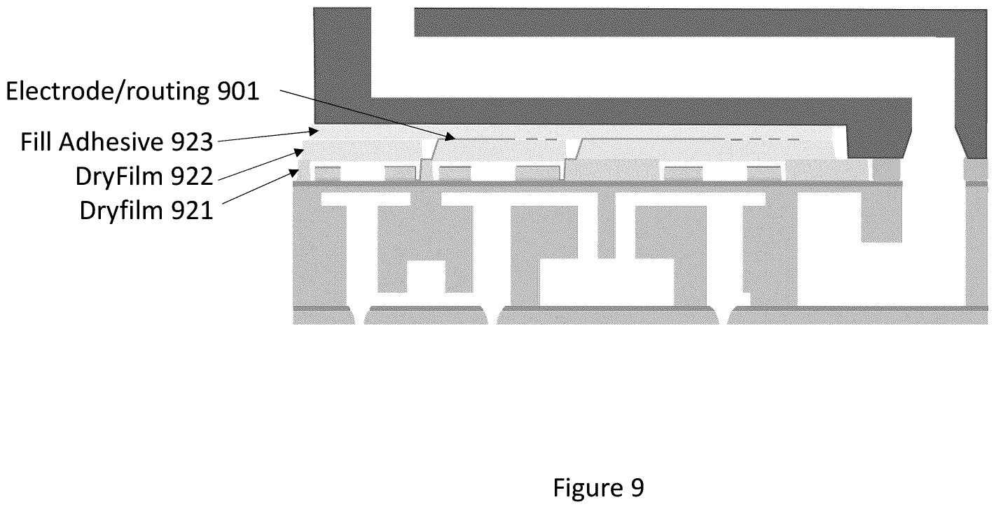

FIG. 9 illustrates some embodiments of a modification of the inkjet printhead in FIG. 4 that includes routing of electrodes and/or traces on the top of dryfilm. Referring to FIG. 9, dryfilms 421 and 422 create a tented structure on top of actuator substrate 401 and the top of dryfilm 422 is coupled to IP 409 via fill adhesive 423. Electrode and trace routing 901 is routed from actuators up to and across dryfilm 422 (and beneath fill adhesive 423). The electrode and trace routing can be on the top surface of membrane layer, on top of any insulating layer over the membrane layer, on the top surface of dryfilm 921, and/or the top surface of dryfilm 922. Such routing can extend between these layers using, for example, via connections.

In some embodiments, a heater circuit is added to one of the surfaces of dryfilm 921 and dryfilm 922. In some embodiments, the heater circuit is an NiCr heater circuit. However, other types of heater circuits can be used.

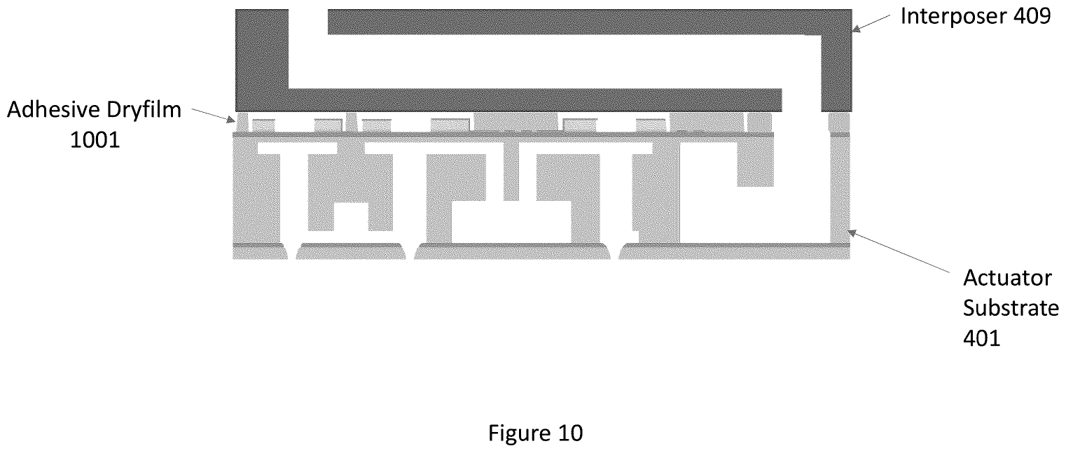

Dryfilm itself can be constructed of numerous possible materials and may include multiple components, including fillers or any of several other photosensitive polymers. In some embodiments, the dryfilm layers have identical material properties. However, in some other embodiments, the dryfilm layers such as, for example, dryfilm layers 421 and 422 do not need to have identical material properties. In some embodiments, the dryfilm materials used in constructing the tented structure come in adhesive versions. Such dryfilm materials can be used with, and laminate onto, non-adhesive dryfilm, but to which other materials may be adhered after patterning. Using the adhesive dryfilm allows leaving out the fill adhesive layer (e.g., fill adhesive 423 of FIG. 4) and simplifying the assembly flow. Further, because using the adhesive dryfilm eliminates a secondary adhesive operation, a single layer of adhesive dryfilm can serve as support layer to which the IP (e.g., IP 409) may be directly attached, with the IP serving as the “roof” of the cavity over the actuator. FIG. 10 illustrates some embodiments of a modification of the inkjet printhead in FIG. 4 in which dryfilm and an IP form the tented structure.

Referring to FIG. 10, adhesive dryfilm 1001 is coupled, or attached, to actuator substrate 401. In some embodiments, dryfilm layer 1001 is a photosensitive polymer laminated onto and over the top of the actuators (e.g., actuator 406), the membrane layer (e.g., membrane layer 405) and electrodes/electrical traces (e.g., electrodes/electrical traces 407) with areas over the membrane layer and actuators having been removed or otherwise extracted during the fabrication process. Dryfilm layer 1001 is coupled, or attached, to IP 409. In this way, IP 409 and dryfilm layer 1001 form the tented structure with a cavity over each actuator and membrane in the cavity.

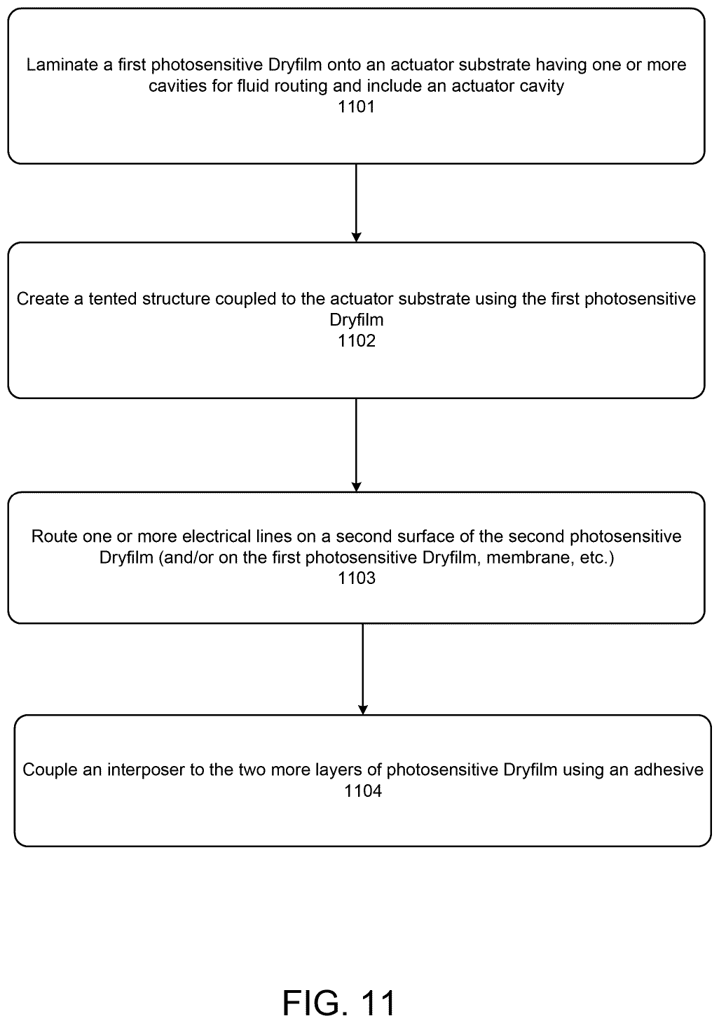

FIG. 11 is a flow diagram of a process for manufacturing an inkjet printhead for expelling a droplet of a fluid through a nozzle orifice. Referring to FIG. 11, process includes laminating a first photosensitive dryfilm onto an actuator substrate having one or more cavities for fluid routing and include an actuator cavity (processing block 1101). In some embodiments, a first side of a membrane is coupled to the actuator substrate and an actuator is coupled to a second side of the membrane that is opposite the first side. The process also includes creating a tented structure coupled to the actuator substrate using the first photosensitive dryfilm (processing block 1102). In some embodiments, the tented structure encloses a cavity around the actuator and large enough to enable the membrane in the cavity to bow without contacting the tented structure.

In some embodiments, the tented structure comprises at least two layers of dryfilm. In some embodiments, at least one of the two layers of dryfilm comprises a photosensitive polymer. In some embodiments, the tented structure includes a first photosensitive dryfilm coupled to a first side of a membrane with an area in the first dryfilm layer over the membrane being open, and a second photosensitive dryfilm having a first surface coupled to the first photosensitive dryfilm to cover the area that is open in the first photosensitive dryfilm over the membrane and to seal the enclosed cavity over the membrane.

In some embodiments, creating the tented structure includes coupling an interposer to the first routing one or more electrical lines dryfilm to cover the area that is open in the first dryfilm layer over the membrane and to seal the enclosed cavity over the membrane.

In some embodiments, the method also optionally includes routing one or more electrical lines on a second surface of the second photosensitive dryfilm (processing block 1103). In some embodiments, the second surface of the second photosensitive dryfilm is on an opposite side of the second photosensitive dryfilm from the first surface. The routing of the one or more electrical lines can be on the top surface of membrane layer, on top of any insulating layer over the membrane layer, on the top surface of the first photosensitive dryfilm layer, and/or the top surface of second photosensitive dryfilm layer, with the routing extending between these layers using, for example, via connections.

In some embodiments, the method also optionally includes coupling an interposer to the two more layers of photosensitive dryfilm using an adhesive (e.g., a fill adhesive) (processing block 1104).

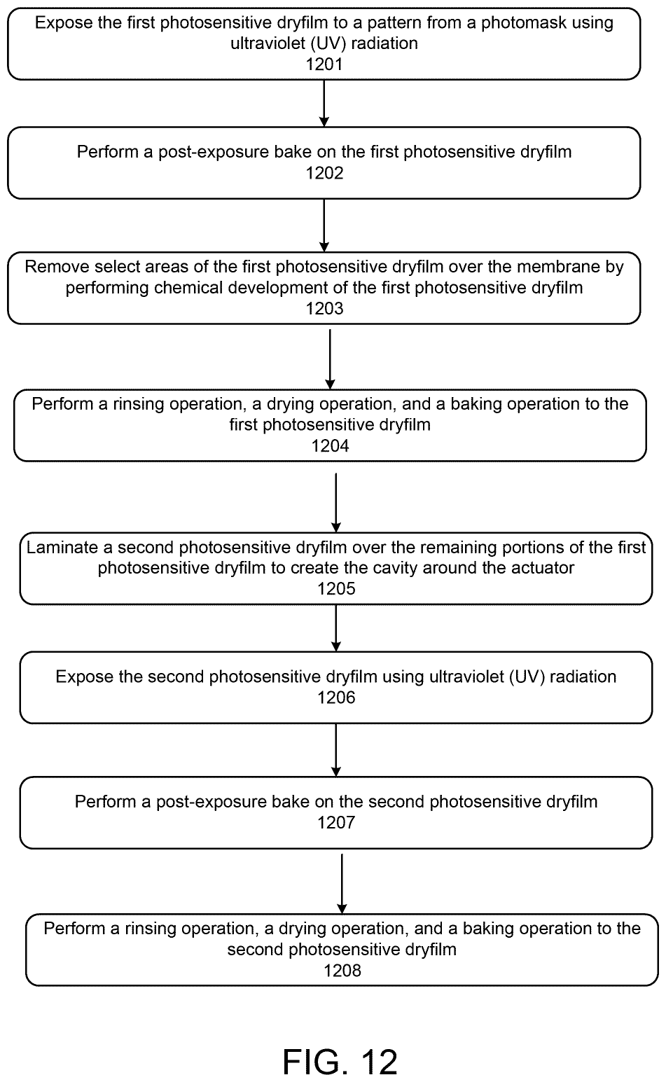

FIG. 12 is a flow diagram of a process for creating some embodiments of a tented structure. The process of FIG. 12 can be used to create the tented structure of, for example, but not limited to, FIGS. 4 and 8-11. Referring to FIG. 12, exposing the first photosensitive dryfilm to a pattern from a photomask using ultraviolet (UV) radiation (processing block 1201) and performing a post-exposure bake on the first photosensitive dryfilm (processing block 1202). Next, the process includes removing select areas of the first photosensitive dryfilm over the membrane by performing chemical development of the first photosensitive dryfilm (processing block 1203) and performing, to the first photosensitive dryfilm, a rinsing operation, a drying operation, and a baking operation (processing block 1204).

After fabricating the first dryfilm layer, the process laminates a second photosensitive dryfilm over the remaining portions of the first photosensitive dryfilm to create the cavity around the actuator (processing block 1205) and exposes the second photosensitive dryfilm using ultraviolet (UV) radiation (processing block 1206). Next, the process includes performing a post-exposure bake on the second photosensitive dryfilm (processing block 1207) and thereafter performs a rinsing operation, a drying operation, and a baking operation to the second photosensitive dryfilm (processing block 1208). Note that given an initial objective of creating cavities over the actuators, the process conditions associated with some of the above operations, such as lamination pressure/temperature, exposure levels, and bake temperatures are designed to allow for effective “tenting” of the second dryfilm layer.

There is a number of example embodiments described herein.

Example 1 is an inkjet printhead comprising: a first actuator substrate having one or more cavities for fluid routing and include an actuator cavity; an actuator stack coupled to the first structure and positioned at least partially over the actuator cavity, the actuator stack comprising a membrane, an actuator coupled to a first side of the membrane, and a tented structure coupled to the actuator substrate to create an enclosed cavity large enough to enable the membrane in the cavity to bow without contacting the tented structure.

Example 2 is the inkjet printhead of example 1 that may optionally include that the tented structure comprises one or more layers of dryfilm.

Example 3 is the inkjet printhead of example 2 that may optionally include that at least one of the one or more layers of dryfilm comprises a photosensitive polymer.

Example 4 is the inkjet printhead of example 2 that may optionally include that the tented structure comprises: a first dryfilm layer coupled to the first side of the membrane with an area in the first dryfilm layer over the membrane being open, and a second dryfilm layer having a first surface coupled to the first dryfilm layer to cover the area that is open in the first dryfilm layer over the membrane and to seal the enclosed cavity over the membrane.

Example 5 is the inkjet printhead of example 4 that may optionally include that the area in the first dryfilm layer over the membrane being open as a result of a portion of the first dryfilm being removed during fabrication.

Example 6 is the inkjet printhead of example 4 that may optionally include that the first and second dryfilm layers have different properties.

Example 7 is the inkjet printhead of example 4 that may optionally include one or more electrical lines routed on one or more of: a second surface of the second dryfilm layer, the second surface of the second dryfilm layer being on an opposite side of the second dryfilm layer from the first surface; the first dryfilm layer; and the membrane.

Example 8 is the inkjet printhead of example 2 that may optionally include an interposer coupled to the one or more layers of dryfilm.

Example 9 is the inkjet printhead of example 8 that may optionally include that the interposer is coupled to the one or more layers of dryfilm using an adhesive.

Example 10 is the inkjet printhead of example 8 that may optionally include that a portion of the one or more layers of dryfilm operate as a travel stop with respect to a glue line coupling the interposer to the first structure.

Example 11 is the inkjet printhead of example 2 that may optionally include an interposer, and wherein the tented structure comprises a first dryfilm layer coupled to the first side of the membrane with an area in the first dryfilm layer over the membrane being open, and wherein the interposer is coupled to the first dryfilm layer to cover the area that is open in the first dryfilm layer over the membrane and to seal the enclosed cavity over the membrane.

Example 12 is a method of manufacturing an inkjet printhead for expelling a droplet of a fluid through a nozzle orifice, where the method comprises: laminating a first photosensitive dryfilm onto an actuator substrate having one or more cavities for fluid routing and include an actuator cavity, wherein a first side of a membrane is coupled to the actuator substrate and an actuator is coupled to a second side of the membrane that is opposite the first side; and creating a tented structure coupled to the actuator substrate using the first photosensitive dryfilm, the tented structure enclosing a cavity around the actuator and large enough to enable the membrane in the cavity to bow without contacting the tented structure.

Example 13 is the method of example 12 that may optionally include that the tented structure comprises at least two layers of dryfilm.

Example 14 is the method of example 13 that may optionally include that at least one of the two layers of dryfilm comprises a photosensitive polymer.

Example 15 is the method of example 14 that may optionally include that the tented structure comprises: the first photosensitive dryfilm coupled to the first side of the membrane with an area in the first dryfilm layer over the membrane being open, and a second photosensitive dryfilm having a first surface coupled to the first photosensitive dryfilm to cover the area that is open in the first photosensitive dryfilm over the membrane and to seal the enclosed cavity over the membrane.

Example 16 is the method of example 15 that may optionally include that creating the tented structure comprises: exposing the first photosensitive dryfilm to a pattern from a photomask using ultraviolet (UV) radiation; performing a post-exposure bake on the first photosensitive dryfilm; removing select areas of the first photosensitive dryfilm over the membrane by performing chemical development of the first photosensitive dryfilm; performing, to the first photosensitive dryfilm, a rinsing operation, a drying operation, and a baking operation; and laminating the second photosensitive dryfilm over the first photosensitive dryfilm to create the cavity around the actuator.

Example 17 is the method of example 16 that may optionally include exposing the second photosensitive dryfilm using ultraviolet (UV) radiation; performing a post-exposure bake on the second photosensitive dryfilm; and performing, to the second photosensitive dryfilm, a rinsing operation, a drying operation, and a baking operation.

Example 18 is the method of example 15 that may optionally include routing one or more electrical lines on one or more of: a second surface of the second photosensitive dryfilm, the second surface of the second photosensitive dryfilm being on an opposite side of the second photosensitive dryfilm from the first surface; the first dryfilm layer; and the membrane.

Example 19 is the method of example 13 that may optionally include coupling an interposer to the two more layers of photosensitive dryfilm using an adhesive.

Example 20 is the method of example 12 that may optionally include creating the tented structure comprising coupling an interposer to the first photosensitive dryfilm to cover the area that is open in the first dryfilm layer over the membrane and to seal the enclosed cavity over the membrane.

Example 21 is the method of example 18 that may optionally include that a portion of the one or more layers of dryfilm operate as a travel stop with respect to a glue line coupling the interposer to the first structure.

Depending on the embodiment, certain acts, events, or functions of any of the processes or algorithms described herein can be performed in a different sequence, can be added, merged, or left out altogether (e.g., not all described operations or events are necessary for the practice of the algorithm).

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements or steps. Thus, such conditional language is not generally intended to imply that features, elements or steps are in any way required for one or more embodiments or that one or more embodiments necessarily include logic for deciding, with or without other input or prompting, whether these features, elements or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, or Z). Thus, such disjunctive language is not generally intended to, and should not, imply that certain embodiments require at least one of X, at least one of Y, and at least one of Z to each be present.

While the above detailed description has shown, described, and pointed out novel features as applied to various embodiments, it can be understood that various omissions, substitutions, and changes in the form and details of the devices or algorithms illustrated can be made without departing from the spirit of the disclosure. As can be recognized, certain embodiments described herein can be embodied within a form that does not provide all of the features and benefits set forth herein, as some features can be used or practiced separately from others. The scope of certain embodiments disclosed herein is indicated by the appended claims rather than by the foregoing description. All changes which come within the meaning and range of equivalency of the claims are to be embraced within their scope.

We claim:

1. An inkjet printhead comprising:
a first actuator substrate having one or more cavities for fluid routing and include an actuator cavity;
an actuator stack coupled to the first structure and positioned at least partially over the actuator cavity, the actuator stack comprising
a membrane,
an actuator coupled to a first side of the membrane, and
a tented structure coupled to the actuator substrate to create an enclosed cavity large enough to enable the membrane in the cavity to bow without contacting the tented structure.

2. The inkjet printhead of claim 1 wherein the tented structure comprises one or more layers of dryfilm.

3. The inkjet printhead of claim 2 wherein at least one of the one or more layers of dryfilm comprises a photosensitive polymer.

4. The inkjet printhead of claim 2 wherein the tented structure comprises:
a first dryfilm layer coupled to the first side of the membrane with an area in the first dryfilm layer over the membrane being open, and
a second dryfilm layer having a first surface coupled to the first dryfilm layer to cover the area that is open in the first dryfilm layer over the membrane and to seal the enclosed cavity over the membrane.

5. The inkjet printhead of claim 4 wherein the area in the first dryfilm layer over the membrane being open as a result of a portion of the first dryfilm being removed during fabrication.

6. The inkjet printhead of claim 4 wherein the first and second dryfilm layers have different properties.

7. The inkjet printhead of claim 4 further comprising one or more electrical lines routed on one or more of:
a second surface of the second dryfilm layer, the second surface of the second dryfilm layer being on an opposite side of the second dryfilm layer from the first surface;
the first dryfilm layer; and
the membrane.

8. The inkjet printhead of claim 2 further comprising an interposer coupled to the one or more layers of dryfilm.

9. The inkjet printhead of claim 8 wherein the interposer is coupled to the one or more layers of dryfilm using an adhesive.

10. The inkjet printhead of claim 8 wherein a portion of the one or more layers of dryfilm operate as a travel stop with respect to a glue line coupling the interposer to the first structure.

11. The inkjet printhead of claim 2 further comprising an interposer, and wherein the tented structure comprises a first dryfilm layer coupled to the first side of the membrane with an area in the first dryfilm layer over the membrane being open, and wherein the interposer is coupled to the first dryfilm layer to cover the area that is open in the first dryfilm layer over the membrane and to seal the enclosed cavity over the membrane.

12. A method of manufacturing an inkjet printhead for expelling a droplet of a fluid through a nozzle orifice, the method comprising:
laminating a first photosensitive dryfilm onto an actuator substrate having one or more cavities for fluid routing and include an actuator cavity, wherein a first side of a membrane is coupled to the actuator substrate and an actuator is coupled to a second side of the membrane that is opposite the first side; and
creating a tented structure coupled to the actuator substrate using the first photosensitive dryfilm, the tented structure enclosing a cavity around the actuator and large enough to enable the membrane in the cavity to bow without contacting the tented structure.

13. The method of claim 12 wherein the tented structure comprises at least two layers of dryfilm.

14. The inkjet printhead of claim 13 wherein at least one of the two layers of dryfilm comprises a photosensitive polymer.

15. The inkjet printhead of claim 14 wherein the tented structure comprises:
the first photosensitive dryfilm coupled to the first side of the membrane with an area in the first dryfilm layer over the membrane being open, and
a second photosensitive dryfilm having a first surface coupled to the first photosensitive dryfilm to cover the area that is open in the first photosensitive dryfilm over the membrane and to seal the enclosed cavity over the membrane.

16. The method of claim 15 wherein creating the tented structure comprises:
exposing the first photosensitive dryfilm to a pattern from a photomask using ultraviolet (UV) radiation;
performing a post-exposure bake on the first photosensitive dryfilm;
removing select areas of the first photosensitive dryfilm over the membrane by performing chemical development of the first photosensitive dryfilm;
performing, to the first photosensitive dryfilm, a rinsing operation, a drying operation, and a baking operation; and
laminating the second photosensitive dryfilm over the first photosensitive dryfilm to create the cavity around the actuator.

17. The method of claim 16 further comprising:
exposing the second photosensitive dryfilm using ultraviolet (UV) radiation;
performing a post-exposure bake on the second photosensitive dryfilm; and
performing, to the second photosensitive dryfilm, a rinsing operation, a drying operation, and a baking operation.

18. The inkjet printhead of claim 15 further comprising routing one or more electrical lines on one or more of:
a second surface of the second photosensitive dryfilm, the second surface of the second photosensitive dryfilm being on an opposite side of the second photosensitive dryfilm from the first surface;
the first dryfilm layer; and
the membrane.

19. The inkjet printhead of claim 13 further comprising coupling an interposer to the two more layers of photosensitive dryfilm using an adhesive.

20. The inkjet printhead of claim 12 wherein creating the tented structure comprising coupling an interposer to the first photosensitive dryfilm to cover the area that is open in the first dryfilm layer over the membrane and to seal the enclosed cavity over the membrane.

21. The inkjet printhead of claim 18 wherein a portion of the one or more layers of dryfilm operate as a travel stop with respect to a glue line coupling the interposer to the first structure.
